(19) United States
(12) Patent Application Publication
(10) Pub. No.: US 2024/0194604 A1
(43) Pub. Date: Jun. 13, 2024

(54) MATERIAL FOR METAL LINE IN SEMICONDUCTOR DEVICE, METAL LINE IN SEMICONDUCTOR DEVICE, AND METHOD FOR FORMING METAL LINE IN SEMICONDUCTOR DEVICE

(71) Applicant: Samsung Electronics Co., Ltd., Suwon-si (KR)

(72) Inventors: Eunyoung LEE, Suwon-si (KR); Wonwoong CHUNG, Suwon-si (KR); Buseo CHOI, Suwon-si (KR); Kkotchorong PARK, Suwon-si (KR); Seulgi BAE, Suwon-si (KR); Uisuk JUNG, Suwon-si (KR); Dong-Chan LIM, Suwon-si (KR)

(73) Assignee: Samsung Electronics Co., Ltd., Suwon-si (KR)

(21) Appl. No.: 18/357,403

(22) Filed: Jul. 24, 2023

(30) Foreign Application Priority Data
Dec. 13, 2022 (KR) 10-2022-0173981

(51) Int. Cl. H01L 23/532; H01L 21/768; H01L 23/528

(52) U.S. Cl. CPC H01L 23/53223; H01L 21/76864; H01L 23/528; H01L 23/53238; H01L 23/53266

(57) ABSTRACT

The described technology relates generally to a material for a metal line in a semiconductor device including an alloy including aluminum as a main material, copper, and an element X, wherein the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2, a metal line in a semiconductor device including the alloy, and a method of forming a metal line in a semiconductor device.

### CROSS-REFERENCE TO RELATED APPLICATION

This application claims priority to and the benefit under 35 U.S.C. § 119 of Korean Patent Application No. 10-2022-0173981 filed in the Korean Intellectual Property Office on Dec. 13, 2022, the entire contents of which are incorporated herein by reference.

### BACKGROUND

### 1. Field

This disclosure relates to a material for a metal line in a semiconductor device, a metal line in a semiconductor device, and a method of forming a metal line in a semiconductor device.

### 2. Description of the Related Art

As semiconductor chips become smaller, reliability due to EM (electromigration) and SM (stress migration) degradation according to design rule shrinkage of BEOL (back end of line) metal lines may be emerging as a problem. In a case of DRAM, in order to improve characteristics of a transistor, an Al line is first formed and then annealed to passivate Si dangling bonding that forms a trap of a channel, wherein a material for the passivation remains on the Al line and deteriorates the SM reliability degradation. The SM reliability degradation of the Al line may be caused by diffusion of Al atoms or voids through Al grain boundaries due to a difference between Al with a large coefficient of thermal expansion and surrounding materials with a relatively small coefficient of thermal expansion. Accordingly, the present inventors have conducted research and development on an Al alloy doped with a material capable of enhancing stress resistance and reducing or preventing the Al diffusion through the Al grain boundaries during the segregation.

### SUMMARY

Various example embodiments may provide a material for a metal line in a semiconductor device capable of improving, or solving, or helping to mitigate a reliability degradation problem caused by movement of Al atoms and/or voids through Al grain boundaries that is due to residual stress associated with a difference in coefficients of thermal expansion between Al having a large coefficient of thermal expansion and surrounding materials having a relatively small coefficient of thermal expansion.

A material for a metal line in a semiconductor device according to some example embodiments includes an alloy including aluminum as a main material, copper, and an element X or a material having element X, wherein the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2.

In some example embodiments, the element X or the material having element X, may have a hexagonal close packed (HCP) or body-centered cubic (BCC) structure.

In some example embodiments, the element X or the material having element X, may have a body-centered cubic (BCC) structure.

In some example embodiments, the element X may include tungsten.

In some example embodiments, the alloy may be composed of aluminum, copper, and tungsten.

In some example embodiments, the aluminum may be included at about 99.0 wt % to about 99.8 wt % based on the total amount of the alloy.

In some example embodiments, the copper and tungsten may be included in an amount of about 0.1 wt % to about 0.5 wt %, respectively, based on the total amount of the alloy.

In some example embodiments, the copper and tungsten may be included in the same weight.

A metal line in a semiconductor device according to some example embodiments includes: an oxide layer and a lower metal layer buried in the oxide layer; a barrier layer on a portion of a whole surface of the oxide layer including the lower metal layer; an alloy on the barrier layer; a reflectance reducing layer on the alloy; and a passivation layer surrounding the barrier layer, the alloy, and the reflectance reducing layer, wherein the alloy includes aluminum as a main material, and includes copper and an element X or a material having element X. At this time, the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2.

In some example embodiments, the alloy may be the same as the aforementioned material for a metal line in a semiconductor device.

In some example embodiments, the oxide layer may include silica.

In some example embodiments, the lower metal layer may include tungsten.

In some example embodiments, the barrier layer may include TiAl, TiN, TiSiN, WN, TaN, Ta, Ti, Ru, or a combination thereof.

In some example embodiments, the reflectance reducing layer may include TiN, Al, or a combination thereof.

In some example embodiments, the passivation layer may include silica, a silicon nitride, or a combination thereof.

In some example embodiments, the alloy may be disposed on the whole surface of the barrier layer, and then etched together with the barrier layer and the reflectance reducing layer; the barrier layer may be disposed on a portion of the whole surface of the oxide layer including the lower metal layer; and the passivation layer may be disposed on the oxide layer where the barrier layer is not disposed to surround the etched barrier layer, the etched alloy, and the etched reflectance reducing layer.

A method of forming a metal line in a semiconductor device according to some example embodiments includes: forming an oxide layer and a lower metal layer buried in the oxide layer on a semiconductor substrate; forming a barrier layer on the whole surface of the oxide layer including the lower metal layer; forming an alloy on the barrier layer; forming a reflectance reducing layer on the alloy; performing a photo and etching process to perform metal line patterning on the alloy; passivating the metal line patterned alloy, the barrier layer, and the reflectance reducing layer with an insulator; and performing heat treatment, wherein the alloy includes aluminum as a main material and includes copper and an element X or a material having element X. In some example embodiments, the element X or the material having element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2.

In some example embodiments, the alloy may be the same as the aforementioned material for a metal line in a semiconductor device.

In some example embodiments, the insulator may include silica, a silicon nitride, or a combination thereof.

In some example embodiments, the heat treatment may be performed at a temperature between about 200° C. and about 500° C. while flowing a gas including H₂, N₂, D₂, Ar, or a combination thereof.

In some example embodiments, the alloy may be deposited to a thickness of about 400 nm to about 700 nm at a temperature of about 400° C. to about 450° C. using a PVD method.

In some example embodiments, the alloy deposited using the PVD method may have purity of greater than or equal to about 99.999%.

According to some example embodiments, stress due to grain growth may be reduced by suppressing grain growth after heat treatment, and the alloy hinders the movement of atoms to provide excellent resistance to electromigration (EM) and stress migration (SM), which are requirements of the PVD process. Therefore, according to some example embodiments, reliability due to EM (electromigration) and SM (stress migration) degradation may be improved.

### BRIEF DESCRIPTION OF THE DRAWINGS

FIG. 1 is a view showing how copper (Cu) blocks movement of voids or atoms at the grain boundary of an alloy according to Comparative Example 1.

FIG. 2 is a view showing how copper (Cu) and tungsten (W) block movement of voids or atoms at the grain boundary of the alloy according to Example 1.

FIG. 3 is a graph showing the average size (area) of grain boundaries before and after heat treatment of alloys according to Example 1 and Comparative Example 1.

FIG. 4 is a graph showing the coefficient of thermal expansion according to the melting point of various metals.

FIG. 5 is a graph showing the electronegativity according to the atomic radius of various metals.

FIG. 6 is a diagram illustrating a method of forming a metal line of a semiconductor device according to some example embodiments.

### DETAILED DESCRIPTION

Reference will now be made in detail to some example embodiments, which are illustrated in the accompanying drawings, wherein like reference numerals refer to like elements throughout the specification. The drawings and description are to be regarded as illustrative in nature and not restrictive. Further, the accompanying drawings are provided only in order to allow embodiments disclosed in the present specification to be easily understood, and are not to be interpreted as limiting the spirit disclosed in the present specification, and it is to be understood that the present invention includes all modifications, equivalents, and substitutions without departing from the scope and spirit of the present invention.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. In the drawings, the thickness of partial layers and regions are exaggerated for convenience of explanation.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion, and does not necessarily mean “above” in an opposite direction of gravity.

It is to be understood that when one constituent element is referred to as being “connected” or “coupled” to another constituent element, it may be connected or coupled directly to the other constituent element or may be connected or coupled to the other constituent element with a further constituent element intervening therebetween. In contrast, it should be understood that, when it is described that an element is “directly coupled” or “directly connected” to another element, no element is present between the element and the other element.

As used herein, the singular forms “a,” “an,” and “the” may be intended to include the plural forms as well, unless the context clearly indicates otherwise. In addition, it should be understood that the term “include,” “comprise,” or “have” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. Unless explicitly described to the contrary, the word “comprise” and variations such as “comprises” or “comprising” will be understood to imply the inclusion of stated elements but not the exclusion of any other elements.

When terms “about” or “substantially” are used in this specification in connection with a numerical value, it is intended that the associated numerical value include a tolerance of ±10% around the stated numerical value. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Aluminum has been mainly used as a material for a metal line in a semiconductor device according to conventional arts. Al (13), which has a small atomic number, has a problem in that electromigration (EM) occurs when the number of electrons is large or the speed is high because momentum transfer occurs even by electron flux. Electromigration (EM) is a phenomenon in which metal atoms move by the flow of electrons, causing metal atoms not to exist where they are supposed to be, thereby voids are formed by exiting metal atoms, the exited metal atoms are accumulated to form a hillock, and a bridge is formed and connected to other circuits to lower the performance of a device.

That is, rapid migration of Al occurs through the grain boundary. For example, Al atoms move by electron flow on the left side to form voids, and on the right side, the Al atoms are accumulated and a hillock occurs.

Accordingly, in order to solve the electromigration (EM) phenomenon, an alloy in which aluminum is used as a main material and copper or silicon is added is currently widely used as a material for a metal line.

However, the alloy in which copper or silicon is added to aluminum may not reduce or prevent stress migration, that is, the phenomenon caused by the movement of voids due to the stress gradient, as in aluminum. Therefore, in the case of a conventional semiconductor device, the alloy, which is a material for a metal line, is functionally affected during various heat treatments when the metal line is formed or in subsequent processes, and thus reliability is seriously damaged due to degradation by stress migration. For example, in the case of DRAM, the phenomenon of disconnection of the metal line is becoming more and more common.

The material for a metal line in a semiconductor device according to some example embodiments include aluminum as a main material and an alloy including copper and element X or a material including element X, wherein, by limiting the element X to an element that satisfies all of the following three requirements, the reliability problem due to the EM (electromigration) and SM (stress migration) degradation may be solved, and for example, the durability of the metal line of the semiconductor device may be improved by improving the metal line disconnection defect phenomenon.

1) A coefficient of thermal expansion (CTE) is greater than about 0.55 ppm/K and less than about 5 ppm/K.

2) A melting point (MP) is greater than about 3000° C.

3) Electronegativity is greater than about 2.2, or an atomic radius is less than or equal to about 120 pm or greater than or equal to about 160 pm.

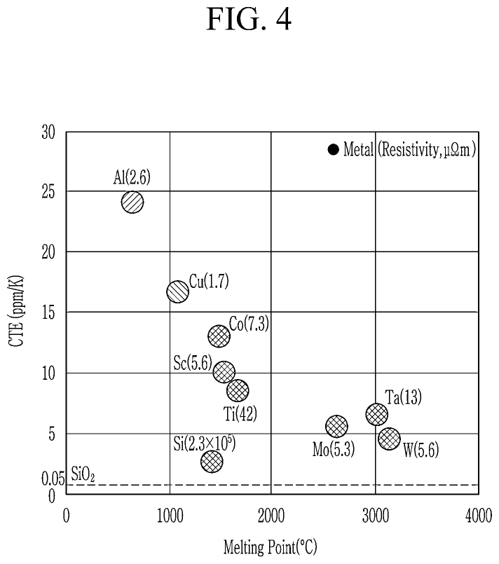

As described above, since the SM reliability degradation of the aluminum line is caused by the movement of aluminum atoms or voids through the Al grain boundary due to the residual stress caused by a difference between aluminum having a large coefficient of thermal expansion and surrounding materials having a relatively small coefficient of thermal expansion, that is, stress due to the difference in coefficients of thermal expansion (CTE), it may be advantageous to introduce a material that has a smaller difference in coefficient of thermal expansion from silica, which is a lower layer of an alloy including aluminum, into an existing alloy of aluminum and copper. Referring to FIG. 4, silicon (Si) and tungsten (W) are examples of metals having a small difference in coefficient of thermal expansion from silica having a coefficient of thermal expansion of 0.55 ppm/K, and all of these metal elements have a coefficient of thermal expansions greater than about 0.55 ppm/K but less than about 5 ppm/K, indicating that these metal elements are primarily suitable for the element X.

On the other hand, since the higher the melting point of the metal element, the lower the void generation rate, it may be advantageous to select a metal element having a higher melting point from the viewpoint of void resistance. Referring to FIG. 4, it can be seen that tungsten (W) has the highest melting point among silicon (Si) and tungsten (W), having a melting point of greater than about 3000° C., and thus tungsten (W) may be most suitable for the element X.

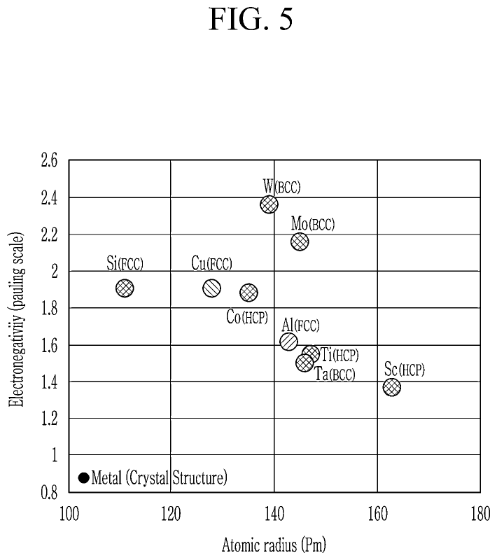

Furthermore, copper added to aluminum, which is an existing alloy, is present at the Al grain boundary, and reduces or prevents the movement of voids or atoms, thereby suppressing electromigration and stress migration to some extent, but copper does not show excellent performance in terms of stress migration suppression ability. Accordingly, the inventors of the present invention conducted research repeatedly to confirm the reason, and as a result, the reason is likely to be that copper has a higher solid solubility with Al, and has a face-centered cubic crystal structure that is the same as that of aluminum. Therefore, according to some example embodiments, it may be advantageous to use a metal element having lower solid solubility for aluminum as the element X. For example, the lower the solid solubility for aluminum, the higher the possibility of existing at the grain boundary, and thus it can be easily used as a material that acts as a blocking agent at the grain boundary, which is the diffusion path of atom movement. Since a metal element, which has a larger radius difference from a radius of an aluminum atom or a larger electronegativity difference from electronegativity of the aluminum atom or does not have a face-centered cubic crystal structure, may be more suitable for the element X, referring to FIG. 5, tungsten (W) has a similar radius to that of the aluminum atom but electronegativity of about 2.4, which has a large difference from electronegativity (about 1.6) of the aluminum atom, and furthermore, does not have the face-centered cubic crystal structure but has a body-centered cubic crystal structure and thus turns out to be suitable for the element X.

Referring to FIG. 5, scandium (Sc) or silicon (Si) has a larger radius difference from the aluminum atom and thus low solid solubility for aluminum, but as shown in FIG. 4, silicon (Si) has a low melting point of less than or equal to about 3000° C. and may not be suitable for the element X (furthermore, silicon has a face-centered cubic crystal structure, which is the same crystal structure as that of aluminum), and scandium (Sc) has a hexagonal close packed structure, which is a different crystal structure from that of aluminum, but has a coefficient of thermal expansion of about 5.6 ppm/K, which has a larger difference from a coefficient of thermal expansion (about 0.55 ppm/K) of silica, and thus may not be suitable for the element X.

In other words, when the element X does not have a face-centered cubic (FCC) crystal structure but has a hexagonal close packed (HCP) crystal structure or a body-centered cubic (BCC) crystal structure, the solid solubility for aluminum becomes lower.

In other words, when the element X simultaneously satisfies these three requirements, atom diffusion with the element X may be much more easily suppressed compared to other conventional metal elements such as copper and the like, resulting in enhancement of stress migration suppression ability.

For example, in some example embodiments, the element X may include tungsten (W).

For example, in some example embodiments, the alloy may be composed of aluminum, copper, and tungsten. For example, in some example embodiments, the alloy may be an Al—Cu—W alloy. When the alloy is composed of aluminum, copper, and tungsten, the atom diffusion may be most effectively suppressed, and other elements such as titanium and the like may be further added thereto, but this affects a relative content of tungsten and the like and thus does not effectively suppress the atom diffusion, resulting in reducing stress migration suppression ability.

For example, in some example embodiments, the aluminum may be included in an amount of about 99.0 wt % to about 99.8 wt % based on the total amount of the alloy.

For example, in some example embodiments, the copper and tungsten may be included in an amount of about 0.1 wt % to about 0.5 wt %, respectively, based on the total amount of the alloy.

For example, the material for a metal line in a semiconductor device according to some example embodiments may be represented by Chemical Formula 1.

AlₓCu_{y}W_{z} [Chemical Formula 1]

In Chemical Formula 1, x, y, and z are a mixing weight ratio of each element, where x is about 99 wt % to about 99.8 wt %, y is about 0.1 wt % to about 0.5 wt %, and z is about 0.1 wt % to about 0.5 wt %.

The material for a metal line in a semiconductor device according to some example embodiments, as an alloy in which tungsten W is present on the aluminum (AI) grain boundaries, compared with an Al—Cu alloy, may have an effect of more intensively blocking diffusion of atoms or voids than when copper (Cu) alone is present. For example, the alloy, the material for a metal line in a semiconductor device according to some example embodiments, may have smaller grain growth after heat treatment, resulting in reducing the atom diffusion, which may ultimately suppress stress migration and thus improve reliability.

For example, the copper and the tungsten included in the material for a metal line in a semiconductor device according to some example embodiments may be included in the same weight. In some example embodiments, the grain growth after the heat treatment may be the most suppressed to reduce or minimize the atom diffusion, and eventually, increase or maximize the reliability-improving effect according to the stress migration suppression.

The metal line in a semiconductor device according to some example embodiments includes an alloy that is the material for a metal line in a semiconductor device.

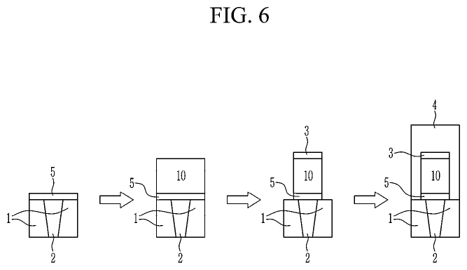

For example, referring to FIG. 6, the metal line in a semiconductor device includes an oxide layer 1 and a lower metal layer 2 buried in the oxide layer; a barrier layer 5 on a portion of a whole surface of the oxide layer including the lower metal layer; an alloy 10 on the barrier layer; a reflectance reducing layer 3 on the alloy; and a passivation layer 4 surrounding the barrier layer, the alloy, and the reflectance reducing layer, wherein the alloy may be the aforementioned alloy.

For example, in some example embodiments, the alloy includes an alloy including aluminum as a main material, and copper and an element X, wherein the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2, or an atomic radius of less than or equal to about 120 pm or greater than or equal to about 160 pm, which may be the same as described above.

For example, in some example embodiments, the oxide layer may include silica. When the oxide layer includes silica, tungsten (W) with a coefficient of thermal expansion having the smallest difference from that of silica may be the most suitable for the element X constituting the aforementioned alloy. Since the oxide layer may function as an insulator for reducing or preventing electrical connection between adjacent metal lines, silica is included in the oxide layer, which may be the most advantageous in terms of this functional aspect. The oxide layer may be deposited on a semiconductor substrate (not shown), and a metal, for example, a tungsten layer, may be filled in the oxide layer, which will be described later.

For example, in some example embodiments, the lower metal layer may include tungsten. The lower metal layer may function as a contact layer that transmits power and a signal by connecting a lower metal line and an alloy (material for a metal line) disposed thereon.

For example, in some example embodiments, the barrier layer may include TiAl, TiN, TiSiN, WN, TaN, Ta, Ti, Ru, or a combination thereof. The barrier layer may be a single layer or a plurality of layers. The barrier layer includes TiAl, TiN, TiSiN, WN, TaN, Ta, Ti, Ru, or a combination thereof, so that a phenomenon in which an alloy formed by an alloy formation process described later diffuses into a lower oxide layer and a lower metal layer to generate voids may be reduced or prevented in advance.

For example, in some example embodiments, the reflectance reducing layer may include TiN, Al, or a combination thereof. The reflectance reducing layer having the aforementioned composition may lower high reflectance of aluminum of the alloy including the aluminum as a main material right under the reflectance reducing layer and thus improve efficiency of a photo process during the metal line forming process described later.

For example, in some example embodiments, the passivation layer may include silica, a silicon nitride, or a combination thereof. The passivation layer has the aforementioned composition to reduce or prevent damage on the alloy including aluminum as a main material during the metal line forming process described later.

For example, in some example embodiments, the alloy is located on the front surface of the barrier layer, and then etched with the barrier layer and the reflectance reducing layer, so that the barrier layer may be located on a portion of the front surface of the oxide layer, while the passivation layer may be located on the oxide layer where the barrier layer is not located to surround the etched barrier layer, the etched alloy, and the etched reflectance reducing layer. In other words, the alloy is deposited on the front surface of the barrier layer deposited on the front surface of the oxide layer, and subsequently, the reflectance reducing layer is deposited on the front surface of the alloy and then etched together with the barrier layer, the alloy, and the reflectance reducing layer through the photo and etching process, so that the barrier layer may be located on a portion of the front surface of the oxide layer, and then the passivation layer may passivate the etched barrier layer, the etched alloy, and the etched reflectance reducing layer.

A method of forming a metal line in a semiconductor device according to in some example embodiments includes: forming an oxide layer and a lower metal layer buried in the oxide layer on a semiconductor substrate; forming a barrier layer on the whole surface of the oxide layer including the lower metal layer; forming an alloy on the barrier layer; forming a reflectance reducing layer on the alloy; performing a photo and etching process to perform metal line patterning on the alloy; passivating the metal line patterned alloy, the barrier layer, and the reflectance reducing layer with an insulator; and performing heat treatment.

For example, in some example embodiments, the alloy includes an alloy including aluminum as a main material, and copper and an element X, wherein the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2, or an atomic radius is less than or equal to about 120 pm or greater than or equal to about 160 pm, which may be the same as described above.

Hereinafter, a method of forming a metal line in a semiconductor device will be described with reference to FIG. 6.

As shown in FIG. 6, in the method of forming a metal line in a semiconductor device according to some example embodiments, first, silica is deposited as an oxide layer 1 on a semiconductor substrate (not shown), and a metal, for example, the tungsten layer 2, is buried.

Subsequently, a barrier layer 5 is deposited to be about 500 Å (50 nm) or less on the front surface of the oxide layer 1 including the tungsten layer 2. In some example embodiments, the barrier layer 5 may be deposited in a plasma enhanced chemical vapor deposition (PECVD) method but is not necessarily limited thereto. After depositing the barrier layer 5, a CMP process or the like may be performed to further make it thinner.

Subsequently, on the barrier layer 5, the aforementioned material for a metal line in a semiconductor device, an alloy including aluminum as a main material, may be deposited to form an about 4000 Å (400 nm) to about 5000 Å-thick (500 nm) alloy or alloy layer 10, and then a TiN layer 3 as the reflectance reducing layer may be formed to be about 300 Å (30 nm) to about 700 Å (70 nm) thick on the alloy or alloy layer 10. The alloy or the alloy layer 10 may be deposited to be about 400 nm to about 700 nm thick at a high temperature of about 380° C. to about 450° C. in a PVD (Physical Vapor Deposition) method, and the TiN layer 3, the reflectance reducing layer, may be deposited to be about 100 Å (10 nm) to about 1000 Å (100 nm) thick. In some example embodiments, the alloy 10 deposited in the PVD method may have purity of about 99.999% or higher.

Subsequently, on the TiN layer 3, a photoresist pattern is formed and then, photo-processed. The photoresist pattern should be thick enough to serve as a mask during an etching process using plasma, which will be described later.

Subsequently, the alloy or the alloy layer 10 is selectively removed together with the barrier layer 5 and the TiN layer 3 through etching, for example, a dry etching process using a plasma in which a mixture of Cl₂ and BCl₃ is activated.

Then, as shown in FIG. 6, the dry etching using the photoresist pattern as a mask is performed to pattern the alloy or the alloy layer, forming a metal line. Herein, the metal line should secure a photoresist margin in the previous process to have some selectivity to a photoresist.

Subsequently, after the dry etching process, the photoresist pattern is removed, and then washing is performed. In some example embodiments, no residue is generated by the barrier layer 5, and above all, the alloy or an alloy of the alloy layer 10 may be reduced or prevented in advance from diffusion into the oxide layer 1 or its lower metal layer, the tungsten layer 2.

Subsequently, after capping the metal line with an insulator, the alloy or the alloy layer 10 and the TiN layer 3 as the reflectance reducing layer may be passivated. In some example embodiments, the insulator may include silica, a silicon nitride, or a combination thereof. The alloy or the alloy layer 10 is passivated using the insulator and may be reduced or prevented from damage.

Then, a heat treatment process (annealing) is performed by flowing a gas while being passivated. In some example embodiments, the heat treatment process may be performed by flowing a gas such as hydrogen gas (H₂), nitrogen gas (N₂), deuterium gas (D₂), argon gas (Ar), and the like at about 200° C. to about 500° C.

Hereinafter, some example embodiments are illustrated in more detail with reference to examples. These examples, however, are not in any sense to be interpreted as limiting the scope of the present disclosure.

### Suppression of Grain Growth Before and After Heat Treatment of Al—Cu Alloy and Al—Cu—W Alloy

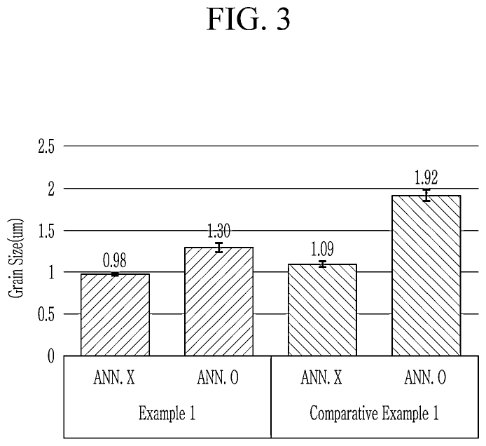

An Al—Cu alloy including Al and Cu in each amount of about 99.5 wt % and about 0.5 wt % (Comparative Example 1), an Al—Cu—W alloy including Al, Cu, and W in each amount of about 99.0 wt %, about 0.5 wt %, and about 0.5 wt % (Example 1), an Al—Cu—W alloy including Al, Cu, and W in each amount of about 99.0 wt %, about 0.8 wt %, and about 0.2 wt % (Example 2), and an Al—Cu—W alloy including Al, Cu, and W in each amount of about 99.0 wt %, about 0.2 wt %, and about 0.8 wt % (Example 3) are respectively heat-treated at about 400° C. for about 120 minutes and then measured with respect to a grain size before and after the heat treatment in an EBSD (Electron BackScattered Diffraction) analysis method (Quantax EBSD Detector, Bruker), and the results are shown in Table 1 and FIG. 3.

TABLE 1

| | Before heat treatment | After heat treatment |
|---|---|---|
| Example 1 | 0.98 | 1.30 |
| Example 2 | 1.00 | 1.56 |
| Example 3 | 1.03 | 1.69 |
| Comparative Example 1 | 1.09 | 1.92 |

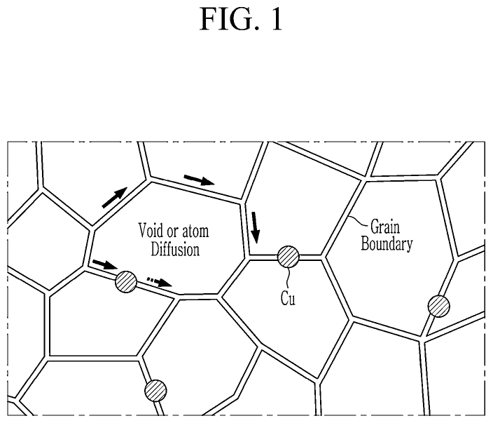

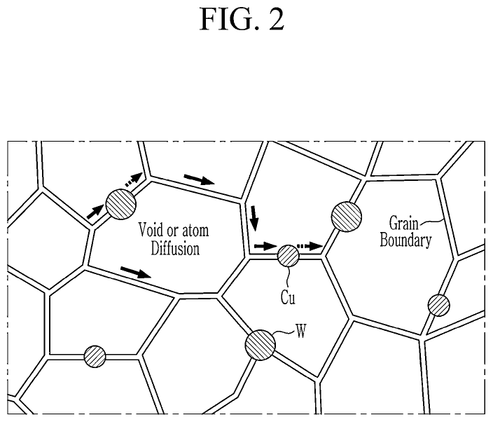

Referring to Table 1 and FIG. 3, the alloy according to Example 1 turns out to be more suppressed from grain growth after the heat treatment than the alloy according to Comparative Example 1, which exhibits that the alloy according to Example 1 further including tungsten (W) may effectively suppress diffusion of voids or atoms, compared with the alloy including copper (Cu) alone according to Comparative Example 1 (e.g., refer to FIGS. 1 and 2).

While the present disclosure has been described in connection with what is presently considered to be some practical embodiments, it is to be understood that the invention is not limited to the disclosed embodiments, but, on the contrary, is intended to cover various modifications and equivalent arrangements included within the spirit and scope of the following claims.

### DESCRIPTION OF SYMBOLS

oxide layer 1
lower metal layer 2
reflectance reducing layer 3
passivation layer 4
barrier layer 5
alloy or alloy layer 10

What is claimed is:

1. A material for a metal line in a semiconductor device, comprising
an alloy including aluminum as a main material, copper, and material having an element X,
wherein the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2.

2. The material of claim 1, wherein
a structure of the element X is one or more of a hexagonal close packed (HCP) or body-centered cubic (BCC).

3. The material of claim 2, wherein
the element X has a body-centered cubic (BCC) structure.

4. The material of claim 1, wherein
the element X includes tungsten.

5. The material of claim 4, wherein
the alloy is composed of aluminum, copper, and tungsten.

6. The material of claim 5, wherein
the aluminum is included at about 99.0 wt % to about 99.8 wt % based on a total amount of the alloy.

7. The material of claim 6, wherein
the copper and tungsten are included in an amount of about 0.1 wt % to about 0.5 wt %, respectively, based on the total amount of the alloy.

8. The material of claim 5, wherein
the copper and tungsten are included in a same weight.

9. A metal line in a semiconductor device, comprising:
an oxide layer and a lower metal layer buried in the oxide layer;
a barrier layer on a portion of a surface of the oxide layer including the lower metal layer;
an alloy having an alloy material on the barrier layer;
a reflectance reducing layer on the alloy; and
a passivation layer surrounding the barrier layer, the alloy, and the reflectance reducing layer,
wherein the alloy material includes an alloy having aluminum as a main material, and copper and an element X, and
the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2.

10. The metal line of claim 9, wherein
the oxide layer includes silica.

11. The metal line of claim 9, wherein
the lower metal layer includes tungsten.

12. The metal line of claim 9, wherein
the barrier layer includes TiAl, TiN, TiSiN, WN, TaN, Ta, Ti, Ru, or a combination thereof.

13. The metal line of claim 9, wherein
the reflectance reducing layer includes TiN, Al, or a combination thereof.

14. The metal line of claim 9, wherein
the passivation layer includes silica, a silicon nitride, or a combination thereof.

15. The metal line of claim 9, wherein
the passivation layer on the oxide layer surrounding an etched barrier layer, an etched alloy, and an etched reflectance reducing layer.

16. A method of forming a metal line in a semiconductor device, comprising:
forming an oxide layer and a lower metal layer buried in the oxide layer on a semiconductor substrate;
forming a barrier layer on a surface of the oxide layer including the lower metal layer;
forming an alloy on the barrier layer;
forming a reflectance reducing layer on the alloy;
performing a photo and etching process to perform metal line patterning on the alloy;
passivating the metal line patterned alloy, the barrier layer, and the reflectance reducing layer with an insulator; and
performing heat treatment,
wherein the alloy includes aluminum as a main material, and copper and an element X, and
the element X has 1) a coefficient of thermal expansion (CTE) of greater than about 0.55 ppm/K and less than about 5 ppm/K, 2) a melting point (MP) of greater than about 3000° C., and 3) electronegativity of greater than about 2.2.

17. The method of claim 16, wherein
the insulator includes silica, a silicon nitride, or a combination thereof.

18. The method of claim 16, wherein
the heat treatment is performed at a temperature between about 200° C. and about 500° C. while flowing a gas including H₂, N₂, D₂, Ar, or a combination thereof.

19. The method of claim 16, wherein
the alloy is deposited to a thickness of about 400 nm to about 700 nm at a temperature of about 400° C. to about 450° C. using a PVD (Physical Vapor Deposition) method.

20. The method of claim 19, wherein
the alloy deposited using the PVD (Physical Vapor Deposition) method has purity of greater than or equal to about 99.999%.
